(19) United States
(12) Patent Application Publication
(10) Pub. No.: US 2002/0028580 A1
(43) Pub. Date: Mar. 7, 2002

(54) SUBSTRATE POLISHING METHOD

(76) Inventors: HARUKI NOJO, TOKYO (JP); KATSUYASU SHIBA, TOKYO (JP)

Correspondence Address: FINNEGAN HENDERSON FARABOW GARRETT &, DUNNER LLP, 1300 I STREET NW, WASHINGTON, DC, 200053315

(21) Appl. No.: 09/321,847

(22) Filed: May 28, 1999

(30) Foreign Application Priority Data
Jun. 1, 1998 (JP) 10-151517

(51) Int. Cl. H01L 21/302; B24B 1/00; H01L 21/461; B24C 1/00

(52) U.S. Cl. 438/689

(57) ABSTRACT

There is disclosed a polishing technology without generation of corrosion on an Al-Cu film formed damascene wiring on a semiconductor substrate by the CMP technology. A chelating agent which forms a chelate compound together with Al and Cu, or a chemical substance which is absorbed onto Al and Cu is added into a slurry to polish, and then a thin film of the chelate compound or the chemical substance is formed on the Al-Cu film. This thin film can suppress movement of electrons (cell reaction) from Al to Cu caused in polishing and suppress elution of Al from the Al-Cu film.

### BACKGROUND OF THE INVENTION

1. Field of the Invention

The present invention relates to a polishing method employed in a semiconductor device manufacturing technology and, more particularly, a substrate polishing method employed in steps of forming plugs and forming damascene wirings of a semiconductor device.

2. Description of the Related Art

In recent years, various fine pattern technologies have been researched and developed with the progress of higher density and submicron wirings of a semiconductor device. As one of technologies which are developed to satisfy requirements for such submicron wirings, there is a chemical mechanical polishing (abbreviated as “CMP” hereinafter) technology. For example, in steps of manufacturing the semiconductor device, this technology is employed to execute planarization of the interlayer dielectric films, formation of the plugs, formation of the damascene wirings, etc.

Next, the formation of the damascene wirings in the semiconductor device with the CMP technology will be explained hereunder. In this case, numeral values disclosed in the explanation of this related art correspond merely to one of particular examples.

FIGS. 1A to 1D are schematic sectional views showing steps of forming damascene wirings with the normal CMP technology.

First, a silicon oxide film 12 of 1.3 μm thickness is formed as an dielectric film on a silicon substrate 11 by the plasma CVD method. A trench 13 which has a width of 0.25 μm and a depth of 0.4 μm is formed in the silicon oxide film 12 by the photolithography method and the etching method (FIG. 1A). An Al-Cu film 14 of 0.8 μm thickness is then formed by the reflow sputtering method (FIG. 1B). In addition, the Al-Cu film 14 is removed from a surface of the silicon oxide film 12 other than the trench 13 by applying the polishing process by means of the CMP technology to thus form an Al-Cu wiring 14a in the trench 13 (FIG. 1C).

In the above polishing process for the Al-Cu film, normally a slurry (its pH is set to 1.5 to 3.0) is employed. In such slurry, alumina particles each having an average particle diameter of 0.05 μm and ferric nitrate are mixed at rates of 1.0 weight % and 5.0 weight % respectively (remaining is a pure water). However, if this sample (FIG. 1B) is polished with this slurry, such a phenomenon occurs that Al around Cu or Cu alloys is eluted into the slurry. As a result, as shown in FIG. 1D, corrosion 15 occurs on a part of the Al-Cu wiring 14a.

Next, the cause of generating the corrosion will be explained hereunder. FIG 2 is an enlarged sectional view showing the surface of the Al-Cu film formed on substrate.

Al 16 and Cu (or Cu alloy) 17 are separate from each other in the Al-Cu film 14. Cu 17 is studded in Al 16 which occupies a major part of the Al-Cu film 14 (a reference 18 indicates a boundary line of Al polycrystal).

In FIG. 2, since electrons (e⁻) are moved from Al 16 to Cu 17 by a cell reaction in areas where Al 16 contacts Cu 17, valence electrons (e^{˜}) are accumulated in Cu 17. Meanwhile, in the interface between the Al-Cu film 14 and a slurry 19, H₂O components of the slurry 19 are decomposed into H⁺ and OH⁻. In this case, the hydrogen ions H⁺ are bonded with the valence electrons (e⁻) which are accumulated in Cu 17, and then changed into H→H₂. Al 16 is ionized and changed into Al⁺ since it has lost the electrons, and then bonded with OH⁻ in the slurry 19 and changed into Al(OH)₃.

The movement of the electrons due to the cell reaction, and the process to generate H₂ and Al⁺ proceeds at the same time on the interface between the Al-Cu film 14 and the slurry 19. Such movement of the electrons due to the cell reaction is also accelerated by generation of H₂. Because of such synergetic action, Al 16 which is located on the interface between the Al-Cu film 14 and the slurry 19 is eluted as Al⁺ to thus cause corrosion 15 on a surface layer of Al 16.

We polished the pure Al film which does not contain Cu, and it has been found that no corrosion is generated. Accordingly, it has been understood that the corrosion is generated around Cu acting as the nucleus However, since Cu is essential material to ensure reliability of the wiring, it seems that removal of Cu from the constituent components is difficult in the existing state.

Also, if ionization (Al⁺) of Al 16 caused on the surface layer can be prevented, theoretically it may be supposed that the corrosion 15 can be suppressed. However, according to the result of the actual experiment using the neutral slurry (its pH is set to 5 to 8) into which silica particles are dispersed, an occurring frequency has been reduced, but generation of the corrosion has not been perfectly suppressed.

In this manner, according to the CMP technology in the prior art, it has been difficult to suppress perfectly the corrosion caused on the Al-Cu film. As a result, there has been the problem that, if the occurring frequency of the corrosion is increased, disconnection of the Al-Cu wirings is produced.

### SUMMARY OF THE INVENTION

It is an object of the present invention to provide a substrate polishing method capable of suppressing generation of corrosion on an alloy film such as an Al-Cu film.

In order to achieve the above object, this present invention provide a substrate polishing method comprising the step of polishing a surface of a substrate which has an alloy film consisting of at least two types of substances by using a slay in which a chemical substance for suppress a cell reaction caused between the two types of substances are added.

As a preferable embodiment, the alloy film consisting of the at least two types of substances is an Al-Cu film, and the chemical substance for suppressing the cell effect caused between Al anid Cu is a chelating agent which form the chelate compound together with Al and Cu.

According to this embodiment, since a thin film of the chelate compound wit Al and Cu is formed on the Al-Cu film, bonding of hydrogen ions H⁺ and valence electrons (e⁻) of the Cu 17 can be blocked, as shown in FIG. 2. Therefore, since movement of electrons (e⁻) from the Al 16 to the Cu 17, i.e, movement of electrons due to the cell reaction can be suppressed, generation of the corrosion can be prevented.

As another preferable embodiment, the alloy film consisting of the at least two types of substances is the Al-Cu film, and the chemical substance for suppressing the cell reaction caused between Al and Cu is a chemical substance absorbing Al and Cu.

According to is embodiment, sine the chemical substance is absorbed by Al and Cu and thus a thin film of the chemical substance is formed on the Al-Cu film, bonding of the hydrogen ions H⁺ and valence electrons (e⁻) of the Cu 17 can be blocked, as shown in FIG. 2. Therefore, since the movement of the electrons (e⁻) from the Al 16 to the Cu 17, i.e., movement of electrons due to the cell reaction can be suppressed, generation of the corrosion can be prevented.

### BRIEF DESCRIPTION OF THE DRAWINGS

FIGS. 1A to 1D are schematic sectional views showing steps of forming damascene wirings according the normal CMP technology;

FIG. 2 is an Al-Cu film formed on a substrate;

FIGS. 3A and 3B are schematic sectional views showing steps of forming damascene wirings by the CMP technology to which a polishing method according to an embodiment of the present invention is applied;

FIG. 4 is a schematic sectional view showing a configuration of a polishing apparatus;

FIG. 5 is a view showing a constitutional formula of a citric acid;

FIG. 6 is a view shown a constitutional formula of an Al chelate compound of the citric acid;

FIGS. 7A to 7C are schematic sectional views showing changes in a sectional shape with the lapsed time when polishing is effected by using a first slurry; and

FIG. 8 is the Al-Cu film formed on the substrate.

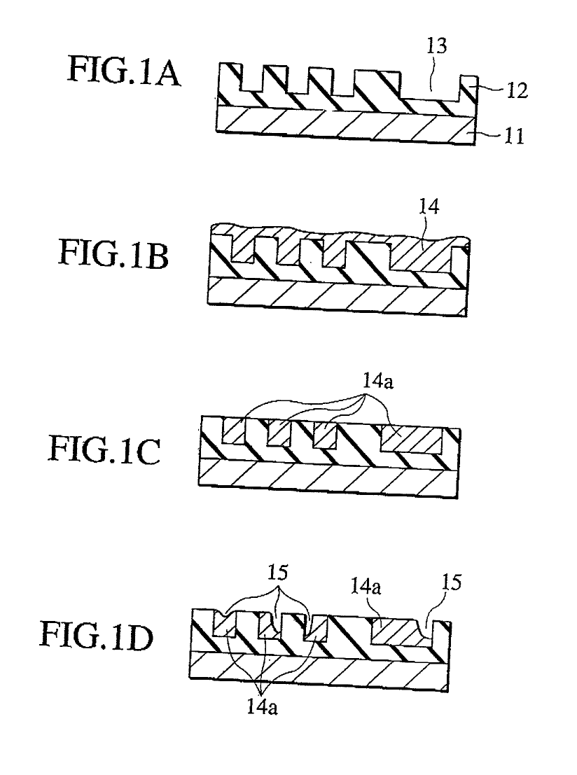

### DETAILED DESCRIPTION OF THE PREFERRED EMBODIMENTS

Embodiments in which a polishing method according to the present invention is applied to steps of forming damascene wirings of a semiconductor device by using the CMP technology will be explained hereinafter.

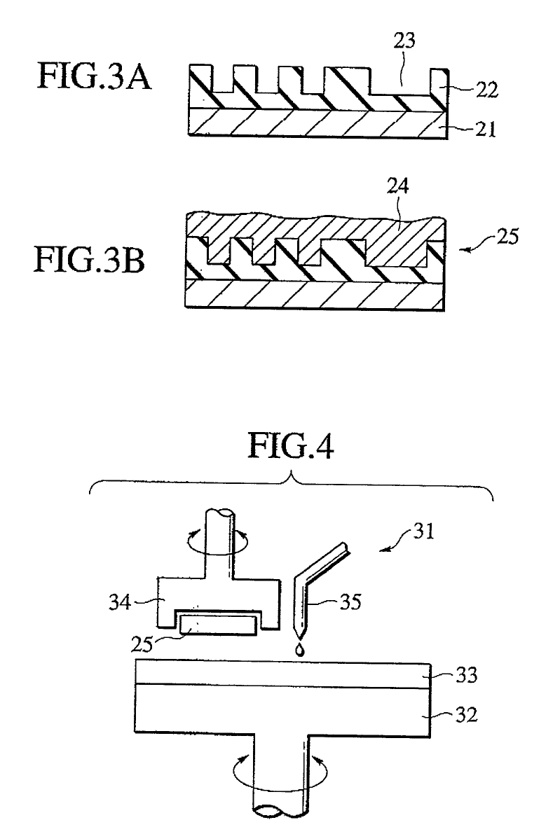

At first, procedures of forming a substrate as a sample will be explained hereunder. FIGS. 3A and 3B are schematic sectional views showing steps of forming damascene wirings by the CMP technology to which a polishing method according to an embodiment of the present invention is applied.

First, a silicon oxide film 22 of 0.9 μm thickness is formed as an dielectric films on a silicon substrate 21 by the plasma CVD method. A trench which has a width of 0.25 μm and a depth of 0.4 μm is then formed in the silicon oxide film 22 by the photolithography method and the etching method (FIG. 3A). An Al-Cu film 24 of 0.8 μm thickness is then formed by the reflow sputtering method, whereby a sample 25 is formed (FIG. 3B). Then, a damascene wirings is formed by applying the CMP to this sample 25 by using a polishing apparatus show in FIG. 4.

The polishing apparatus 31 shown in FIG. 4 comprises a polishing turn table 32 which can be rotated forwardly and reversely, a polishing cloth 33 attached to the turn table 32, a vacuum chuck holder 34 which can be moved vertically and be rotated forwardly and reversely, and a slurry supplying pipe 35 for supplying the slurry onto a surface of the polishing cloth 33.

The sample 25 shown in FIG. 3B is held by the vacuum chuck holder 34 such that a polished surface can be opposed to the polishing cloth 33. The vacuum chuck holder 34 and the polishing turn table 32 are then rotated in predetermined directions respectively such that the polished surface of the sample 25 and the polishing cloth 33 can be moved relatively. In addition, the Al-Cu film 24 formed on the surface of the sample 25 is polished flatly by moving the vacuum chuck holder 34 downward and then pushing the polished surface of the sample 25 against the polishing cloth 33 by a predetermined pressure.

In this case, an amount of the slurry supplied from the slurry supplying pipe 35 in polishing can be controlled by a supply amount controlling means (not shown). Also, a pressure by which the sample 25 is pushed against the polishing cloth 33 can be controlled freely by a compressed air.

Two types of the slurrys are prepared for the sample 25 as constructed above and the polishing apparatus 31.

A first slurry is prepared by mug alumina particles each having an average particle diameter of 0.05 μm, the nitric acid, and the citric acid at rates of 1.0 weight %, 1.0 weight %, and 1.0 weight % respectively (the remaining is a pure water). This slurry is prepared to examine an effect in which chelate compound is produced by the citric acid as a chelating agent together with Al and Cu.

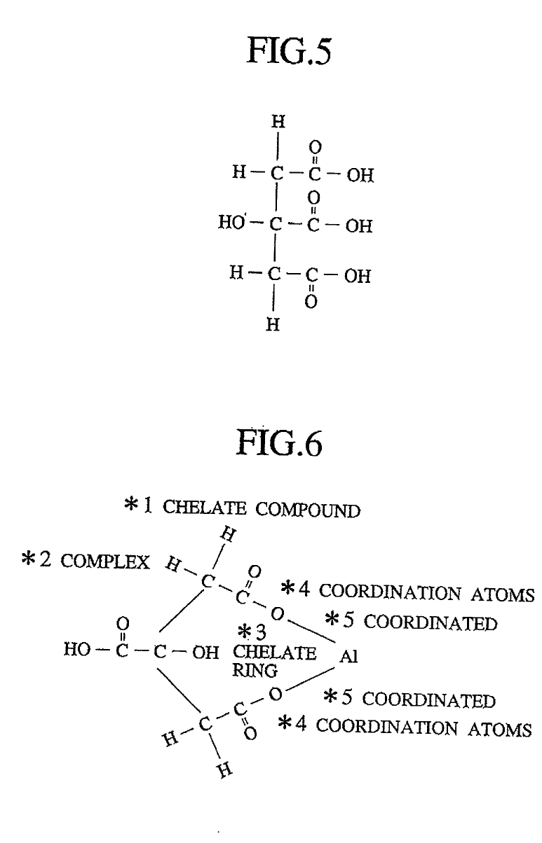

A constitutional formula of the citric acid is shown in FIG. 5 as an example of the chelating agent. A constitutional formula of an Al chelate compound of the citric acid is shown in FIG. 6.

The chelating agent means a multidentate ligand which is coordinate with metal ions to form the chelate compound (*1).

The chelate compound means a general term of a complex (*2) which has a chelate ring. The chelate ring (*3) means a ring structure which is formed when two coordination atoms (*4) or more, each having one molecule or ion, are coordinated (*5) so as to put a metal atom (ion) therebetween.

As the chelating agent employed in the substrate polishing method of the present invention, acrylic acid other than the citric acid may be employed.

A second slurry is prepared by mixing silica particles each having an average particle diameter of 0.05 μm, and amine phosphate at rates of 10 weight %, and 1.0 weight % respectively (the remaining is the pure water). This slurry is prepared to examine an effect in which the amine phosphate a kind of an amine phosphate series surfactant is absobedy Al and Cu.

In this examination, two samples 25 which are formed under the same condition have been prepared, and then respective samples have been polished under the same polishing conditions by using the first and second slurrys respectively. As the polishing conditions, a pressure for pushing the sample 25 against the polishing cloth 33 is set to 300 (gf/cm2), and rotation speeds of the polishing turn table and the vacuum chuck holder are set to 100 (rpm). The conditions are referred to as standard conditions of the polishing.

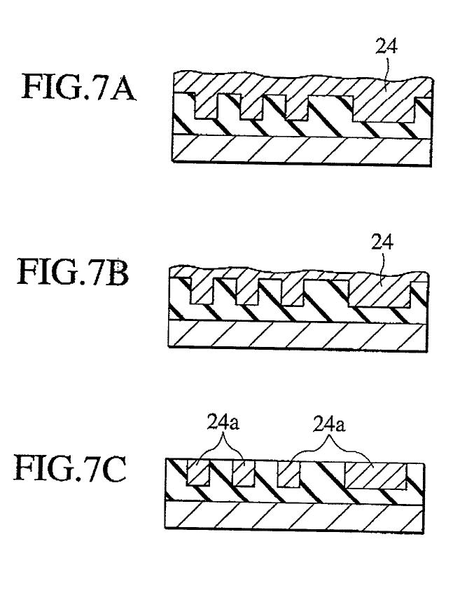

Changes in a sectional shape with the lapsed time when polishing is effected by using a first slurry are shown in FIGS. 7A to 7C. FIGS. 7A to 7C show schematically features of the sectional shape which have been observed by the experiment. Since the similar results have been derived when the polishing is effected by using the second slurry, their explanation made with reference to the drawings showing the sectional shape will be omitted..

FIG. 7A shows the sectional shape derived after the polishing process has been applied for 100 second. FIG. 7B shows the sectional shape derived after the polishing process has been applied for 200 second.

If the slurry described in the column of the related art is employed, sometimes the corrosion is caused at the stage shown in FIG. 7A or FIG. 7B. However, according to the slurry employed in the present embodiment, generation of the corrosion can be suppressed in both cases in FIGS. 7A and 7B. The Al-Cu film 24 acting as the polished film is removed from the surface of the silicon oxide film 22 other than the trench 23 by applying the polishing further more, and thus an Al-Cu wiring 24a is formed in the trench 23, as shown in FIG. 7C. As evident from FIG. 7C, generation of the corrosion has been able to be perfectly suppressed.

Next, the corrosion suppressing phenomenon in the polishing method according to the present embodiment will be explained hereunder.

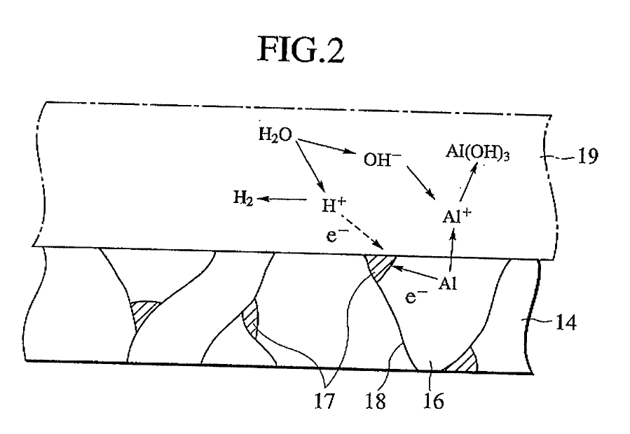

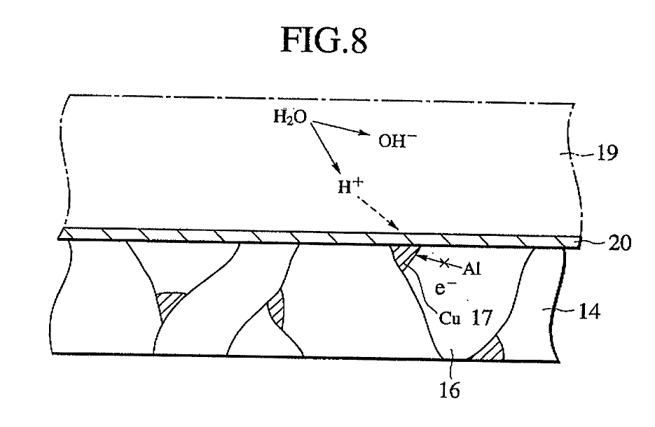

FIG. 8 is an enlarged sectional view showing a surface of the substrate on which the Al-Cu film 14 is formed. In FIG. 8, the same portions as those in FIG. 2 are denoted by the same references.

In the case that the first slurry is employed as the slurry, a chelate compound is produced by the citric acid which is contained in the first slurry as well as Al and Cu, and then attached to a surface of the Al-Cu film 14 as a thin film of the chelate compound 20. At that time, bonding of the hydrogen ions H⁺ which are decomposed fom H₂O in the slurry 19 and the valence electrons (e⁻) which are discharged from Cu 17 can be prevented by the thin film of the chelate compound 20. As a consequence, it may be considered that movement of the electrons (e⁻) fron the Al 16 to the Cu 17 due to the cell reaction can be suppressed and thus the Al 16 can be suppressed from being ionized and eluted into the slurry 19.

It may be supposed that such phenomenon is caused similarly when the second slurry is employed. In other words, if the second slurry is employed, the amine phosphate a kind of the amine phosphate series surfactant is absorbed by Al and Cu to then form a thin film on the surface of the Al-Cu film 14, like the above-mentioned chelate compound. Therefore, it may be supposed that bonding of H⁺ and the valence electrons (e⁻) discharged from Cu 17 can be prevented and thus the movement of the electrons (e⁻) from the Al 16 to the Cu 17 due to the cell reaction can be suppressed.

In this case, the surface of the Al-Cu film 14 is always polished by the alumina particles in polishing, nevertheless the thin film of the chelate compound 20 (or a thin film formed by an adsorption reaction of the amine phosphate) can be constantly formed on the surface of the Al-Cu film 14. Therefore, it may be supposed that bonding of H⁻ and the valence electrons (e⁻) can be prevented.

In addition, in order to examine whether or not the corrosion can be prevented when the chelating agent contained in the first slurry is absorbed by Cu only, with the use of a slurry into which BTA (benzotriazole) and oxalic acid, both can produce the chelate compound onto Cu only, are added and in which the alumina particles or the silica particles are used as a base component, the polishing of the Al-Cu film has been carried out under the standard conditions. However, no corrosion suppressing effect has been able to be recognized. As this result, it has become apparent that the absorption made only by Cu is insufficient to suppress the corrosion and also the corrosion suppressing effect cannot be achieved unless chemical substance such as the citric acid or the amine phosphate salt, which can produce chelate generation or adsorption reaction with both Cu and Al, are added, like the slurry in the present embodiment.

The substrate polish method according to the present invention is not limited to the above embodiment, and various modifications may be applied. For example, if Fe2O3 particles, SiC particles, SiN articles, ZrO particles, TiO₂ particles, etc are employed as the polish particle, or the solvent with no particle is employed, or the polishing is carried out by using the grindstone, etc., the similar effect can also be achieved.

Moreover, the film as the polished object is not limited to the Al-Cu film. The present invention may also be applied commonly material such as an Al alloy film, a Cu alloy film, etc. which can produce the cell reaction.

What is claimed is:

1. A substrate polishing method comprising the step of:
polishing a surface of a substrate which has an alloy film consisting of at least two types of substances by using a slurry in which a chemical substance for suppressing a cell reaction caused between the two types of substances are added.

2. A substrate polishing method according to claim 1, wherein the chemical substance combines with the at least two types of substances and produces a compound.

3. A substrate polishing method according to claim 1, wherein the alloy film consisting of the at least two types of substances is an Al-Cu film, and
the chemical substance for suppressing the cell reaction caused between Al and Cu is a chelating agent which form the chelate compound together with Al and Cu.

4. A substrate polishing method according to claim 1, wherein the chelating agent is formed of an acrylic acid.

5. A substrate polishing method according to claim 3, wherein the chelating agent is formed of a citric acid.

6. A substrate polishing method according to claim 5, wherein the slurry containing the citric acid is prepared by mixing alumina particles, a nitric acid, and a citric acid at rates of 1.0 weight %, 1.0 weight %, and 1.0 weight % into a pure water of 100 respectively.

7. A substrate polishing method according to claim 1, wherein the alloy film consisting of the at least two types of substances is an Al-Cu film, and
the chemical substance for suppressing the cell reaction caused between Al and Cu is a chemical substance having a property to absorb Al and Cu.

8. A substrate polishing method according to claim 7, wherein the chemical substance is formed of an amine phosphate series surfactant.

9. A substrate polishing method according to claim 8, wherein the amine phosphate series surfactant is formed of an amine phosphate.

10. A substrate polish method according to claim 9, wherein the slurry containing the amine phosphate salt is prepared by mixing silica particles and the amine phosphate at rates of 10 weight % and 1.0 weight % into a pure water of 100 respectively.

11. A substrate polishing method according to claim 1, wherein the alloy film consisting of the at least two types of substances is formed to cover an entire surface of the substrate having a trench and holl pattern thereon and to fill the trench and holl pattern, and then a surface of the alloy film is planarized by means of polishing using the slurry.

12. A substrate polishing method according to claim 1, wherein a polishing cloth is pushed against the surface of the substrate which has the alloy film consisting of the at least two types of substances thereon, the substrate and the polishing cloth are moved relatively in this state, and then the slurry in which the chemical substance for suppressing the cell reaction caused between the two types of substances are added is supplied between the surface of the substrate and the polishing cloth.

13. A substrate polishing method according to claim 1, wherein the slurry contains a chemical substance for suppressing the cell reaction caused between the at least two types of substances and polishing particles.
